(19) United States
(12) Patent Application Publication
(10) Pub. No.: US 2011/0256665 A1
(43) Pub. Date: Oct. 20, 2011

(54) STACKED WAFER MANUFACTURING METHOD

(75) Inventors: Akihito Kawai, Ota-Ku (JP); Koichi Kondo, Ota-ku (JP)

(73) Assignee: DISCO CORPORATION, Tokyo (JP)

(21) Appl. No.: 13/077,125

(22) Filed: Mar. 31, 2011

(30) Foreign Application Priority Data
Apr. 15, 2010 (JP) 2010-094386

(51) Int. Cl. H01L 21/50; H01L 21/762

(52) U.S. Cl. 438/109; 438/459; 257/E21.567; 257/E21.499

(57) ABSTRACT

A manufacturing method for a stacked wafer composed of a mother wafer and a stacking wafer bonded together. The mother wafer has a plurality of first semiconductor devices and the stacking wafer has a plurality of second semiconductor devices respectively corresponding to the first semiconductor devices. The manufacturing method includes the steps of bonding the front side of a substrate through a bonding layer to the front side of the stacking wafer, next grinding the back side of the stacking wafer to reduce the thickness of the stacking wafer to a predetermined thickness, next stacking the unit of the stacking wafer and the substrate bonded together on the mother wafer in the condition where the back side of the stacking wafer is opposed to the front side of the mother wafer, thereby bonding electrodes exposed to the back side of each second semiconductor device to electrodes of each first semiconductor device formed on the front side of the mother wafer, and finally grinding the substrate bonded to the front side of the stacking wafer to thereby remove the substrate.

### BACKGROUND OF THE INVENTION

1. Field of the Invention

The present invention relates to a manufacturing method for a stacked wafer configured by bonding a mother wafer having a plurality of first semiconductor devices and a stacking wafer having a plurality of second semiconductor devices.

2. Description of the Related Art

In a semiconductor device fabrication process, a plurality of crossing division lines called streets are formed on the front side of a substantially disk-shaped semiconductor wafer to partition a plurality of regions where a plurality of semiconductor devices such as ICs and LSIs are respectively formed. The semiconductor wafer is cut along the streets to thereby divide the regions where the semiconductor devices are formed from each other, thus manufacturing a plurality of individual semiconductor chips.

For the purposes of size reduction and higher functionality of equipment, a module structure having the following configuration is in practical use. This module structure is such that a plurality of second semiconductor devices are stacked on the front side of a mother wafer having a plurality of first semiconductor devices and that electrodes of each second semiconductor device are respectively connected to electrodes of each first semiconductor device formed on the front side of the mother wafer (see Japanese Patent Laid-open No. 2003-249620, for example). Further, a stacked wafer having this module structure is also in practical use. In this stacked wafer, electrodes are embedded in each second semiconductor device so as to extend from the front side to the back side of each second semiconductor device, and these electrodes exposed to the back side of each second semiconductor device are bonded to the electrodes of each first semiconductor device formed on the front side of the mother wafer.

For the purposes of size reduction and higher functionality of equipment produced by using this stacked wafer, the back side of a stacking wafer having the plural second semiconductor devices is ground to reduce the thickness of the stacking wafer to tens of micrometers before it is stacked on the front side of the mother wafer. However, when the stacking wafer is ground to tens of micrometers in thickness, the stacking wafer loses its rigidity like a sheet of paper, so that it bends. Accordingly, it is difficult to stack the stacking wafer on the mother wafer so that the second semiconductor devices respectively correspond to the first semiconductor devices in proper positions, thus causing faulty electrical continuity between the electrodes of each second semiconductor device and the electrodes of the corresponding first semiconductor device. To prevent the bending of a wafer due to grinding, there has been proposed a method of grinding the back side of the wafer in the condition where a substrate formed from a hard plate is bonded through a wax or the like to the front side of the wafer (see Japanese Patent Laid-open No. 2004-207606, for example).

### SUMMARY OF THE INVENTION

In processing the stacking wafer having the plural second semiconductor devices, the back side of the stacking wafer is ground in the condition where the substrate is bonded through a wax or the like to the front side of the stacking wafer, and bumps are next mounted on the plural electrodes embedded in each second semiconductor device and exposed to the back side thereof. Alternatively, via holes for embedding the electrodes are formed in each second semiconductor device by laser processing and the electrodes are next embedded in these via holes. In mounting the bumps or forming the via holes by laser processing, the stacking wafer is heated. Accordingly, a bonding layer for bonding the substrate to the front side of the stacking wafer must have resistance to a temperature of about 250° C. Accordingly, in removing the substrate from the stacking wafer after grinding the back side of the stacking wafer in the condition where the substrate is bonded through the bonding layer to the front side of the stacking wafer, it is necessary to perform an operation such that the substrate is heated to a temperature higher than 250° C., that the substrate is slid along the front side of the stacking wafer and removed therefrom without applying a load to the stacking wafer, and that the substrate is cooled to ordinary temperature. Therefore, the productivity is low.

It is therefore an object of the present invention to provide a stacked wafer manufacturing method which can eliminate the problem that it is difficult to stack the stacking wafer on the mother wafer so that the second semiconductor devices respectively correspond to the first semiconductor devices in proper positions even when the stacking wafer is ground to be reduced in thickness, thereby improving the productivity.

In accordance with an aspect of the present invention, there is provided a manufacturing method for a stacked wafer configured by bonding a mother wafer having a plurality of first semiconductor devices and a stacking wafer having a plurality of second semiconductor devices, the manufacturing method including a substrate bonding step of bonding the front side of a substrate through a bonding layer to the front side of the stacking wafer; a stacking wafer grinding step of holding a unit of the stacking wafer and the substrate bonded together on a chuck table of a grinding apparatus after performing the substrate bonding step and grinding the back side of the stacking wafer to reduce the thickness of the stacking wafer to a predetermined thickness; a stacking wafer bonding step of stacking the unit of the stacking wafer and the substrate bonded together on the mother wafer in the condition where the back side of the stacking wafer is opposed to the front side of the mother wafer after performing the stacking wafer grinding step, thereby bonding electrodes exposed to the back side of each second semiconductor device to electrodes of each first semiconductor device formed on the front side of the mother wafer; and a substrate removing step of holding a unit of the mother wafer, the stacking wafer, and the substrate bonded together on a chuck table of a grinding apparatus after performing the stacking wafer bonding step and grinding the substrate bonded to the front side of the stacking wafer to thereby remove the substrate from the front side of the stacking wafer.

In accordance with another aspect of the present invention, there is provided a manufacturing method for a stacked wafer configured by bonding a mother wafer having a plurality of first semiconductor devices and a stacking wafer having a plurality of second semiconductor devices, the manufacturing method including a substrate bonding step of bonding the front side of a substrate through a bonding layer to the front side of the stacking wafer; a stacking wafer grinding step of holding a unit of the stacking wafer and the substrate bonded together on a chuck table of a grinding apparatus after performing the substrate bonding step and grinding the back side of the stacking wafer to reduce the thickness of the stacking wafer to a predetermined thickness; a stacking wafer dividing step of dividing the stacking wafer together with the substrate into the plurality of second semiconductor devices after performing the stacking wafer grinding step; a second semiconductor device bonding step of respectively stacking the plurality of second semiconductor devices on the plurality of first semiconductor devices formed on the front side of the mother wafer in the condition where the back side of each second semiconductor device is opposed to the front side of each first semiconductor device after performing the stacking wafer dividing step, thereby bonding electrodes exposed to the back side of each second semiconductor device to electrodes of each first semiconductor device formed on the front side of the mother wafer; and a substrate removing step of holding a unit of the mother wafer, the second semiconductor devices, and the substrate bonded together on a chuck table of a grinding apparatus after performing the second semiconductor device bonding step and grinding the substrate bonded to the front side of each second semiconductor device to thereby remove the substrate from the front side of each second semiconductor device.

In the stacked wafer manufacturing method according to the present invention, the back side of the stacking wafer bonded to the substrate is ground to reduce the thickness of the stacking wafer to a predetermined thickness. Thereafter, the unit of the stacking wafer and the substrate bonded together is stacked on the mother wafer in the condition where the back side of the stacking wafer is opposed to the front side of the mother wafer, thereby bonding the electrodes exposed to the back side of each second semiconductor device of the stacking wafer to the electrodes of each first semiconductor device formed on the front side of the mother wafer. Accordingly, the second semiconductor devices of the stacking wafer can be reliably bonded to the first semiconductor devices of the mother wafer without bending of the stacking wafer reduced in thickness.

In the substrate removing step of removing the substrate from the front side of the stacking wafer, the substrate bonded to the front side of the stacking wafer is removed by grinding, so that no load is applied to the stacking wafer. Accordingly, it is not necessary to perform an operation such that the substrate is heated to a temperature higher than 250° C. for the purpose of removing the substrate from the front side of the stacking wafer, that the substrate is slid along the front side of the stacking wafer and removed therefrom without applying a load to the stacking wafer, and that the substrate is cooled to ordinary temperature. Therefore, the productivity can be improved.

In the stacked wafer manufacturing method according to the present invention, the back side of the stacking wafer bonded to the substrate is ground to reduce the thickness of the stacking wafer to a predetermined thickness. Thereafter, the stacking wafer is divided together with the substrate to obtain the individual second semiconductor devices. Thereafter, the second semiconductor devices are respectively stacked on the first semiconductor devices formed on the front side of the mother wafer in the condition where the back side of each second semiconductor device is opposed to the front side of each first semiconductor device, thereby bonding the electrodes exposed to the back side of each second semiconductor device to the electrodes of each first semiconductor device formed on the front side of the mother wafer. Accordingly, each second semiconductor device reduced in thickness can be easily handled, so that each second semiconductor device can be reliably bonded to each first semiconductor device formed on the front side of the mother wafer.

In the substrate removing step of removing the substrate from the front side of each second semiconductor device, the substrate bonded to the front side of each second semiconductor device is removed by grinding, so that no load is applied to each second semiconductor device.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a mother wafer used in the stacked wafer manufacturing method according to the present invention;

FIG. 2 is a perspective view of a stacking wafer used in the stacked wafer manufacturing method according to the present invention;

FIGS. 3A and 3B are perspective views for illustrating a substrate bonding step in a first preferred embodiment of the stacked wafer manufacturing method according to the present invention;

FIG. 4 is a perspective view for illustrating a stacking wafer grinding step in the first preferred embodiment of the stacked wafer manufacturing method according to the present invention;

FIGS. 5A and 5B are perspective views for illustrating a stacking wafer bonding step in the first preferred embodiment of the stacked wafer manufacturing method according to the present invention;

FIG. 5C is a sectional view of an essential part of the unit of the mother wafer, the stacking wafer, and the substrate shown in FIG. 5B;

FIG. 6 is a perspective view for illustrating a substrate removing step in the first preferred embodiment of the stacked wafer manufacturing method according to the present invention;

FIG. 7 is a perspective view of the unit of the mother wafer and the stacking wafer in the condition after performing the substrate removing step shown in FIG. 6;

FIG. 8 is a perspective view of a stacked wafer obtained by performing a bonding layer removing step in the first preferred embodiment of the stacked wafer manufacturing method according to the present invention;

FIGS. 9A and 9B are perspective views for illustrating a wafer supporting step in a second preferred embodiment of the stacked wafer manufacturing method according to the present invention;

FIG. 10 is a perspective view of a cutting apparatus for performing a stacking wafer dividing step in the second preferred embodiment of the stacked wafer manufacturing method according to the present invention;

FIGS. 11A and 11B are sectional side views for illustrating the stacking wafer dividing step;

FIG. 12 is a perspective view of each second semiconductor device obtained by performing the stacking wafer dividing step;

FIG. 13A is a perspective view for illustrating a second semiconductor device bonding step in the second preferred embodiment of the stacked wafer manufacturing method according to the present invention;

FIG. 13B is a sectional view of an essential part of the unit of the mother wafer, each second semiconductor device, and the substrate shown in FIG. 13A;

FIG. 13C is a perspective view of the unit of the mother wafer, all the second semiconductor devices, and the substrate obtained by the second semiconductor device bonding step;

FIG. 14 is a perspective view for illustrating a substrate removing step in the second preferred embodiment of the stacked wafer manufacturing method according to the present invention;

FIG. 15 is a perspective view of the unit of the mother wafer and the second semiconductor devices in the condition after performing the substrate removing step shown in FIG. 14; and

FIG. 16 is a perspective view of a stacked wafer obtained by performing a bonding layer removing step in the second preferred embodiment of the stacked wafer manufacturing method according to the present invention.

### DETAILED DESCRIPTION OF THE PREFERRED EMBODIMENTS

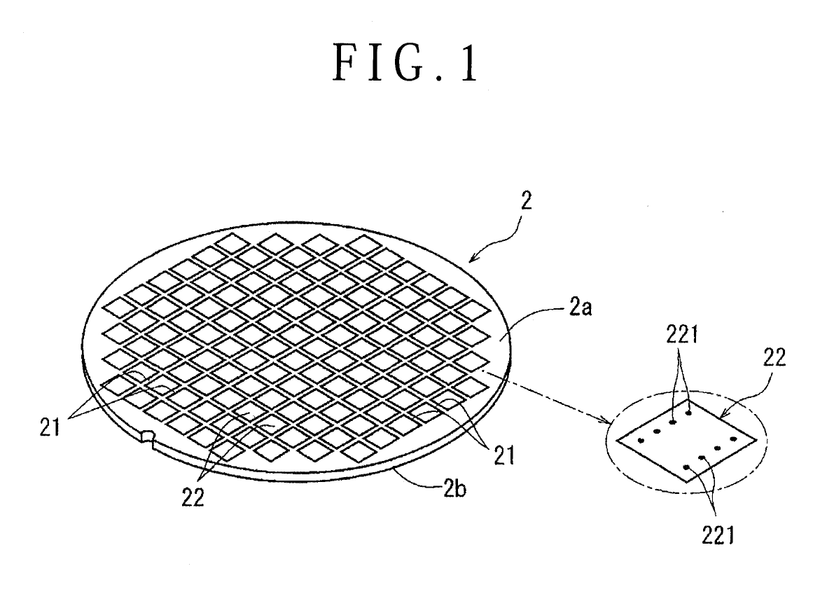

Some preferred embodiments of the stacked wafer manufacturing method according to the present invention will now be described in detail with reference to the attached drawings. FIG. 1 is a perspective view of a mother wafer 2 used in the stacked wafer manufacturing method according to the present invention. The mother wafer 2 shown in FIG. 1 is a disk-shaped silicon wafer having a thickness of 400 μm, for example. The mother wafer 2 has a front side 2a and a back side 2b. A plurality of crossing streets 21 are formed on the front side 2a of the mother wafer 2 to thereby partition a plurality of rectangular regions where a plurality of first semiconductor devices 22 such as ICs and LSIs are respectively formed. Each first semiconductor device 22 is provided with a plurality of electrodes 221 projecting from the front side. These plural electrodes 221 are embedded in each first semiconductor device 22 so as to extend from the front side to the back side of each first semiconductor device 22.

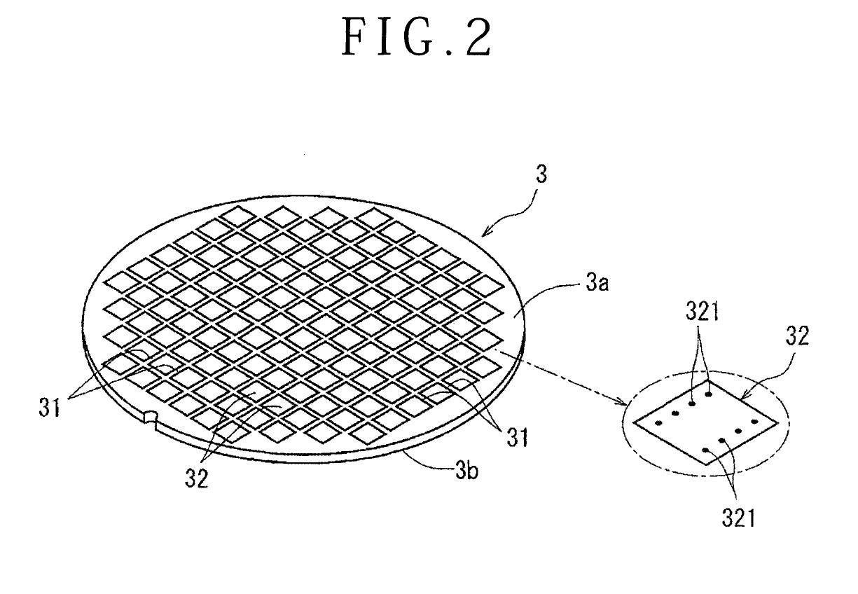

FIG. 2 is a perspective view of a stacking wafer 3 used in the stacked wafer manufacturing method according to the present invention. The stacking wafer 3 shown in FIG. 2 is also a disk-shaped silicon wafer having a thickness of 400 μm, for example. The stacking wafer 3 has a front side 3a and a back side 3b. A plurality of crossing streets 31 are formed on the front side 3a of the stacking wafer 3 to thereby partition a plurality of rectangular regions where a plurality of second semiconductor devices (stacking devices) 32 such as ICs and LSIs are respectively formed. A plurality of electrodes 321 are embedded in each second semiconductor device 32 so as to extend from the front side to the back side of each second semiconductor device 32. The size of each second semiconductor device 32 in the stacking wafer 3 is the same as that of each first semiconductor device 22 in the mother wafer 2, and the plural electrodes 321 of each second semiconductor device 32 respectively correspond to the plural electrodes 221 of each first semiconductor device 22.

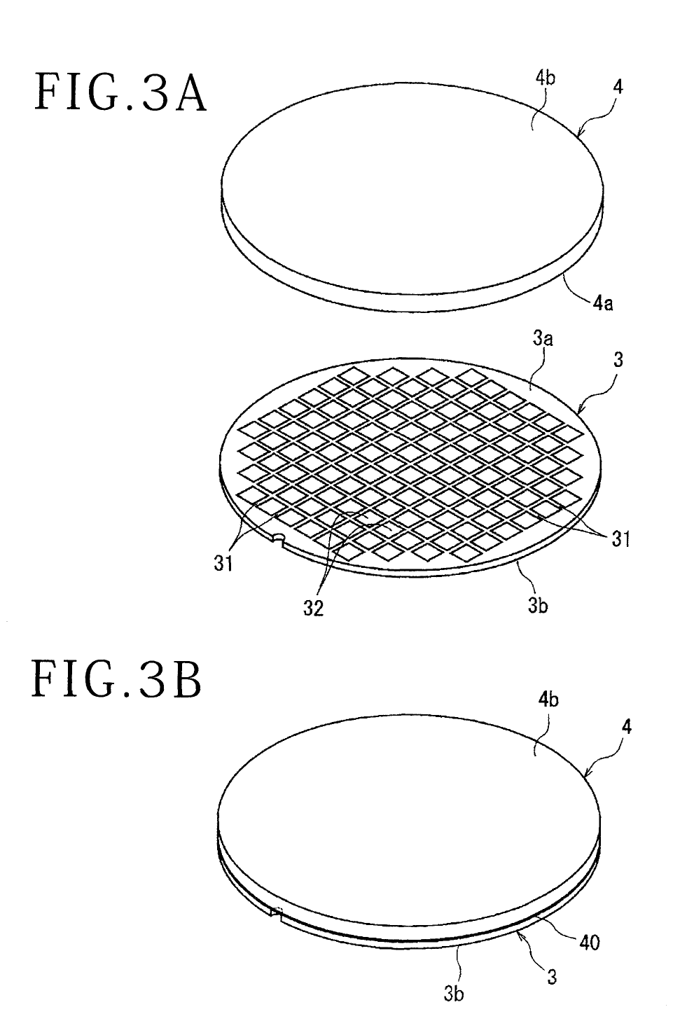

There will now be described a first preferred embodiment of the stacked wafer manufacturing method for bonding the back side of each second semiconductor device 32 to the front side of each first semiconductor device 22. First, a substrate bonding step is performed in such a manner that the front side of a substrate is bonded through a bonding layer to the front side of the stacking wafer 3 having the plural second semiconductor devices 32. More specifically, as shown in FIGS. 3A and 3B, a substrate 4 having a front side 4a and a back side 4b is prepared. The substrate 4 is a disk-shaped silicon substrate having a thickness of 500 μm, for example. The front side 4a of the substrate 4 is bonded through a bonding layer 40 to the front side 3a of the stacking wafer 3. The bonding layer 40 is formed of a material resistant to high temperature, such as epoxy resin. A silicon substrate is preferably used as the substrate 4 because it is easy to work. The thickness of the bonding layer 40 is set to 20 μm, for example.

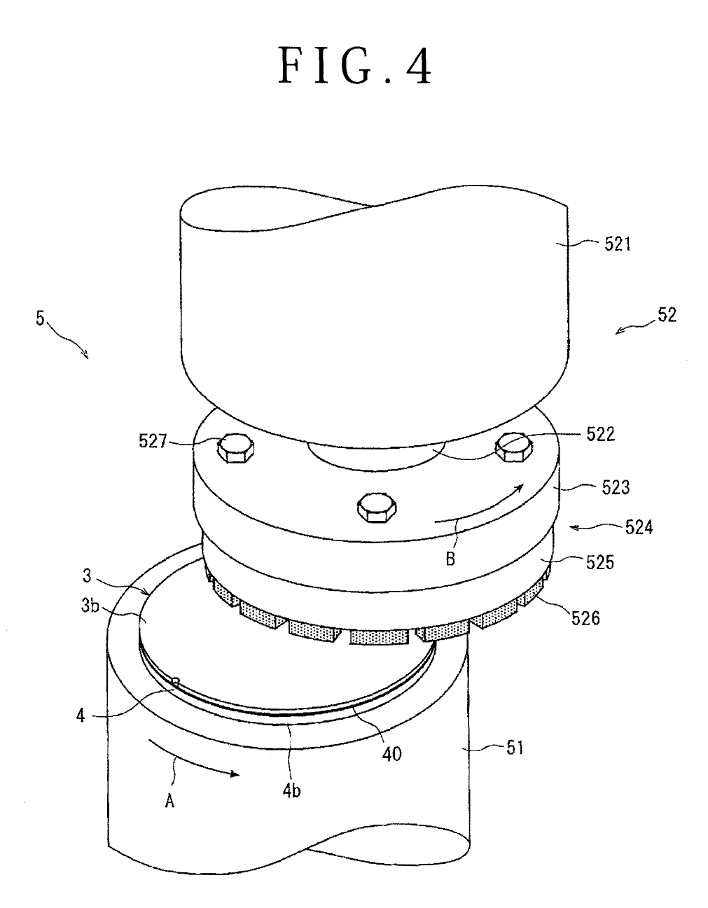

After performing the substrate bonding step mentioned above, a stacking wafer grinding step is performed in such a manner that the unit of the stacking layer 3 and the substrate 4 bonded together is held on a chuck table of a grinding apparatus and the back side 3b of the stacking wafer 3 is ground to reduce the thickness of the stacking wafer 3 to a predetermined thickness. This stacking wafer grinding step is performed by using a grinding apparatus 5 shown in FIG. 4. The grinding apparatus 5 shown in FIG. 4 includes a chuck table 51 for holding a workpiece and grinding means 52 for grinding the workpiece held on the chuck table 51. The chuck table 51 has an upper surface for holding the workpiece under suction. The chuck table 51 is rotatable in the direction shown by an arrow A in FIG. 4. The grinding means 52 includes a spindle housing 521, a rotating spindle 522 rotatably supported to the spindle housing 521 so as to be rotated by a rotational driving mechanism (not shown), a mounter 523 mounted on the lower end of the rotating spindle 522, and a grinding wheel 524 mounted on the lower surface of the mounter 523. The grinding wheel 524 is composed of a circular base 525 and a plurality of abrasive members 526 mounted on the lower surface of the base 525 so as to be annularly arranged along the outer circumference of the base 525. The base 525 is mounted to the lower surface of the mounter 523 by a plurality of fastening bolts 527.

The stacking wafer grinding step using this grinding apparatus 5 is performed in the following manner. First, the unit of the stacking wafer 3 and the substrate 4 bonded together is placed on the chuck table 51 in the condition where the back side 4b of the substrate 4 comes into contact with the upper surface (holding surface) of the chuck table 51 as shown in FIG. 4. In this condition, suction means (not shown) is operated to hold the stacking wafer 3 through the substrate 4 on the chuck table 51 under suction. Accordingly, the back side 3b of the stacking wafer 3 held through the substrate 4 on the chuck table 51 is oriented upward. In the condition where the stacking wafer 3 is held under suction on the chuck table 51 as mentioned above, the chuck table 51 is rotated at 300 rpm, for example, in the direction shown by the arrow A in FIG. 4 and the grinding wheel 524 of the grinding means 52 is also rotated at 6000 rpm, for example, in the direction shown by an arrow B in FIG. 4. Thereafter, the grinding wheel 524 is lowered to bring the abrasive members 526 into contact with the back side 3b of the stacking wafer 3. Thereafter, the grinding wheel 524 is fed downward at a feed speed of 1 μm/sec, for example, thereby grinding the back side 3b of the stacking wafer 3 to reduce the thickness of the stacking wafer 3 to 30 μm, for example.

In this manner, the thickness of the stacking wafer 3 is reduced to a very small thickness of 30 μm by the stacking wafer grinding step. However, since the substrate 4 having high rigidity is attached to the front side 3a of the stacking wafer 3, there is no possibility of bending of the stacking wafer 3. After performing the stacking wafer grinding step, a bump is soldered to each electrode 321 exposed to the back side of each second semiconductor device 32 of the stacking wafer 3. In the case that the electrodes 321 exposed to the back side of each second semiconductor device 32 are not formed in fabricating the stacking wafer 3, via holes for embedding the electrodes in each second semiconductor device may be formed by laser processing after performing the stacking wafer grinding step. Thereafter, an insulating film is formed on the inner surface of each via hole and the electrodes are next embedded into the via holes, respectively.

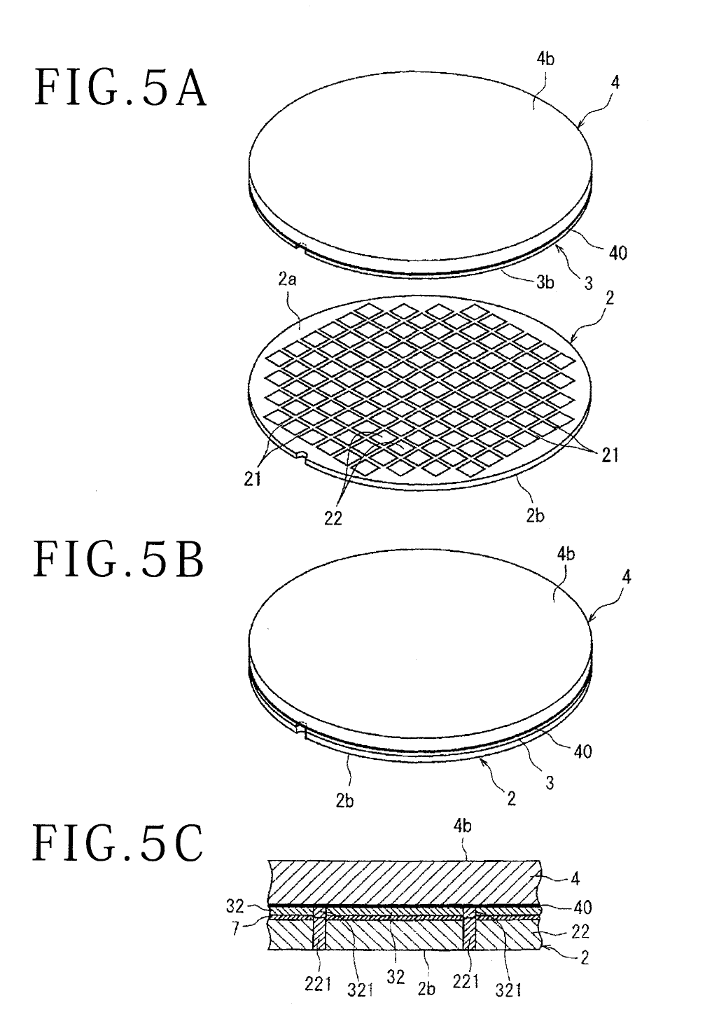

After performing the stacking wafer grinding step mentioned above, a stacking wafer bonding step is performed in such a manner that the unit of the stacking wafer 3 and the substrate 4 is stacked on the mother wafer 2 in the condition where the back side 3b of the stacking wafer 3 is opposed to the front side 2a of the mother wafer 2, thereby bonding the electrodes exposed to the back side of each second semiconductor device 32 to the electrodes of each first semiconductor device 22 formed on the front side 2a of the mother wafer 2. More specifically, as shown in FIGS. 5A and 5B, the stacking wafer 3 bonded to the substrate 4 is stacked on the mother wafer 2 so that the back side 3b of the stacking wafer 3 is opposed to the front side 2a of the mother wafer 2. In this condition, as shown in FIG. 5C, the electrodes 321 exposed to the back side of each second semiconductor device 32 are respectively bonded to the electrodes 221 of each first semiconductor device 22 formed on the front side 2a of the mother wafer 2. In this stacking wafer bonding step, the back side 3b of the stacking wafer 3 is bonded to the front side 2a of the mother wafer 2 in the condition where the substrate 4 is bonded to the front side 3a of the stacking wafer 3. Accordingly, there is no possibility of bending of the stacking wafer 3 having a very small thickness in the stacking wafer bonding step. That is, the electrodes 321 exposed to the back side of each second semiconductor device 32 can be reliably bonded to the electrodes 221 of each first semiconductor device 22 formed on the front side 2a of the mother wafer 2. In this stacking wafer bonding step, a resin 7 as an underfill material is preferably interposed between the front side 2a of the mother wafer 2 and the back side of each second semiconductor device 32 as shown in FIG. 5C.

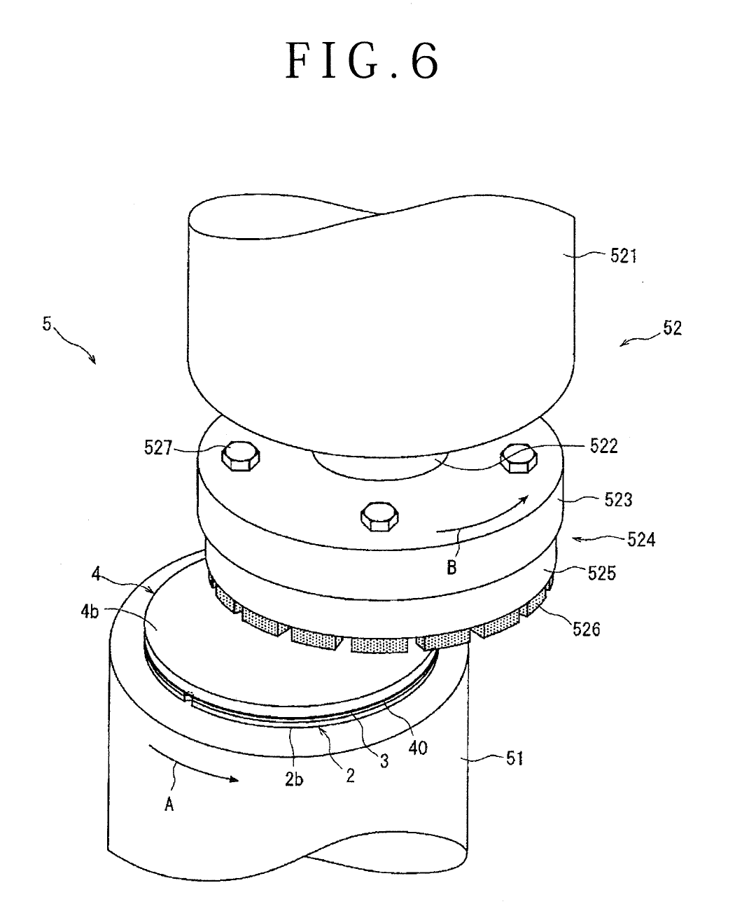

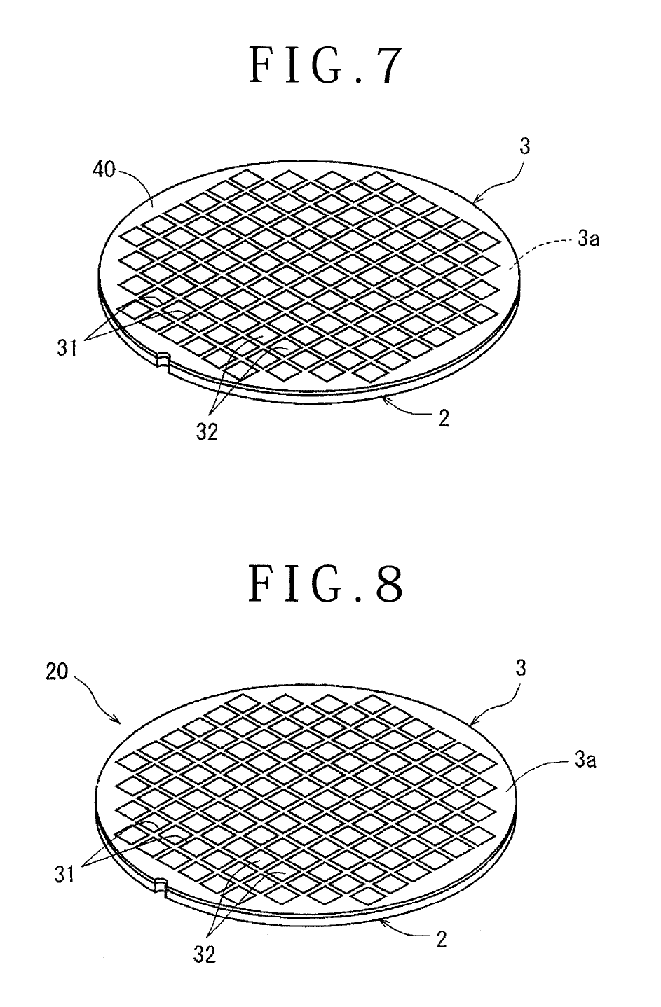

After performing the stacking wafer bonding step mentioned above, a substrate removing step is performed in such a manner that the unit of the mother wafer 2, the stacking wafer 3, and the substrate 4 bonded together is held on a chuck table of a grinding apparatus and the substrate 4 bonded to the front side 3a of the stacking wafer 3 is ground to be removed. This substrate removing step may be performed by using the grinding apparatus 5 shown in FIG. 4. The substrate removing step using the grinding apparatus 5 is performed in the following manner. First, the unit of the mother wafer 2, the stacking wafer 3, and the substrate 4 bonded together is placed on the chuck table 51 in the condition where the back side 2b of the mother wafer 2 comes into contact with the upper surface (holding surface) of the chuck table 51 as shown in FIG. 6. In this condition, the suction means is operated to hold the unit of the mother wafer 2, the stacking wafer 3, and the substrate 4 on the chuck table 51 under suction. Accordingly, the back side 4b of the substrate 4 constituting this unit held on the chuck table 51 is oriented upward. In the condition where the unit of the mother wafer 2, the stacking wafer 3, and the substrate 4 is held under suction on the chuck table 51 as mentioned above, the chuck table 51 is rotated at 300 rpm, for example, in the direction shown by an arrow A in FIG. 6 and the grinding wheel 524 of the grinding means 52 is also rotated at 6000 rpm, for example, in the direction shown by an arrow B in FIG. 6. Thereafter, the grinding wheel 524 is lowered to bring the abrasive members 526 into contact with the back side 4b of the substrate 4. Thereafter, the grinding wheel 524 is fed downward at a feed speed of 1 μm/sec, for example, by an amount of 500 μm, for example. As a result, the substrate 4 having a thickness of 500 μm is ground to be removed from the front side 3a of the stacking wafer 3 as shown in FIG. 7.

In the substrate removing step mentioned above, the substrate 4 bonded to the front side 3a of the stacking wafer 3 is removed by grinding, so that no load is applied to the stacking wafer 3. Accordingly, it is not necessary to perform an operation as in the prior art such that the substrate 4 is heated to a temperature higher than 250° C. for the purpose of removing the substrate 4 from the front side 3a of the stacking wafer 3, that the substrate 4 is slid along the front side 3a of the stacking wafer 3 and removed therefrom without applying a load to the stacking wafer 3, and that the substrate 4 is cooled to ordinary temperature. Therefore, the productivity can be improved. In the condition after performing the substrate removing step, the bonding layer 40 used to bond the front side 4a of the substrate 4 to the front side 3a of the stacking wafer 3 in the substrate bonding step still remains on the front side 3a of the stacking wafer 3 as shown in FIG. 7.

Accordingly, the bonding layer 40 left on the front side 3a of the stacking wafer 3 is removed by using a solvent such as methyl ethyl ketone (bonding layer removing step). As a result, a stacked wafer 20 shown in FIG. 8 is obtained. That is, the stacked wafer 20 is composed of the mother wafer 2 and the stacking wafer 3 stacked on the mother wafer 2 so that the back side 3b of the stacking wafer 3 is opposed to the front side 2a of the mother wafer 2 and that the electrodes exposed to the back side of each second semiconductor device 32 are respectively bonded to the electrodes of each first semiconductor device 22 formed on the front side 2a of the mother wafer 2.

There will now be described a second preferred embodiment of the stacked wafer manufacturing method according to the present invention. Also in the second preferred embodiment, the substrate bonding step and the stacking wafer grinding step are similarly performed as in the first preferred embodiment.

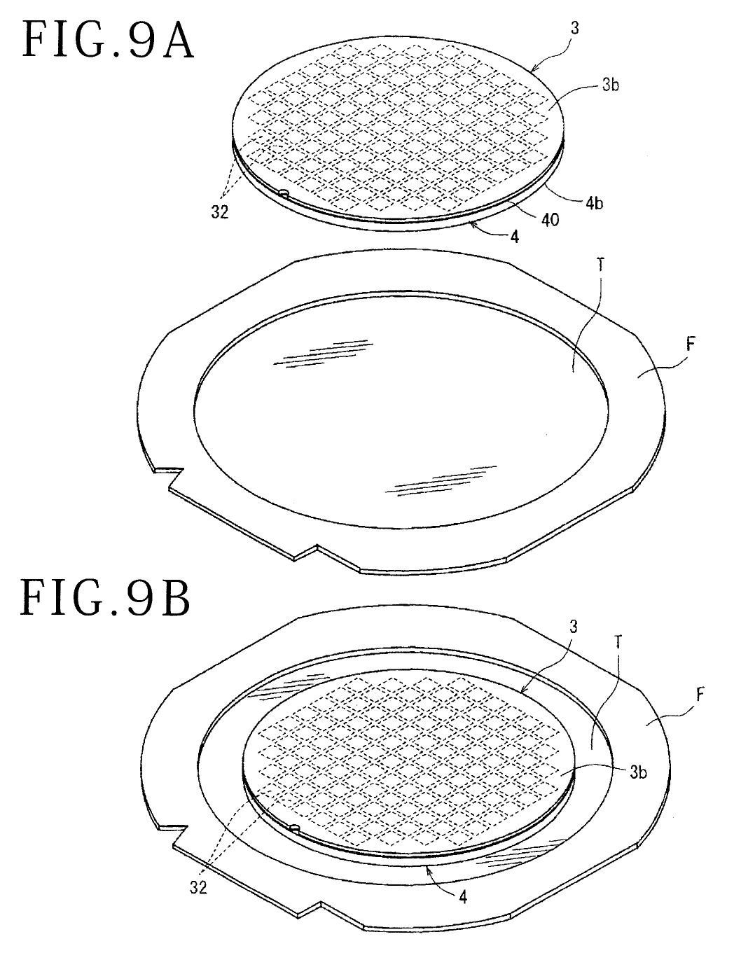

After performing the substrate bonding step and the stacking wafer grinding step, a wafer supporting step is performed in such a manner that the unit of the stacking wafer 3 and the substrate 4 bonded together is supported through a dicing tape to an annular frame in the condition where the stacking wafer 3 or the substrate 4 is attached to the front side (adhesive surface) of the dicing tape supported to the annular frame. More specifically, as shown in FIGS. 9A and 9B, a dicing tape T is supported at its outer circumferential portion to an annular frame F so as to close the inner opening of the annular frame F. The back side 4b of the substrate 4 bonded to the front side 3a of the stacking wafer 3 is attached to the front side (adhesive surface) of the dicing tape T. The dicing tape T is composed of a base sheet and an adhesive layer formed on the front side of the base sheet. For example, the base sheet is formed of polyvinyl chloride (PVC) and has a thickness of 100 μm. The adhesive layer is formed of acrylic resin and has a thickness of about 5 μm.

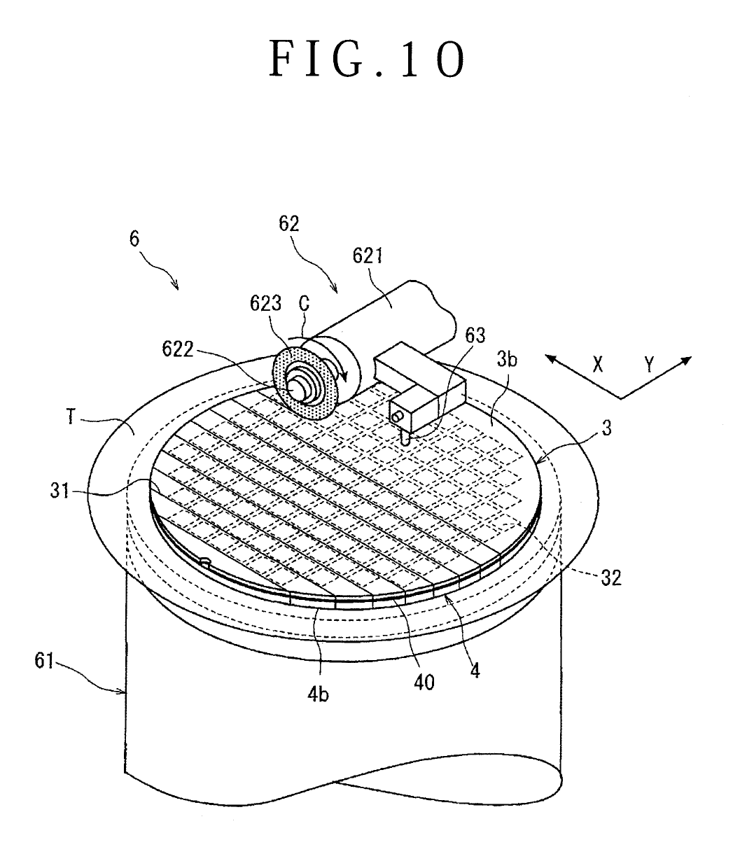

After performing the wafer supporting step mentioned above, a stacking wafer dividing step is performed in such a manner that the stacking wafer 3 is divided together with the substrate 4 into the individual second semiconductor devices 32. This stacking wafer dividing step is performed by using a cutting apparatus 6 shown in FIG. 10. The cutting apparatus 6 shown in FIG. 10 includes a chuck table 61 for holding the stacking wafer 3 as a workpiece, cutting means 62 for cutting the workpiece held on the chuck table 61, and imaging means 63 for imaging the workpiece held on the chuck table 61. The chuck table 61 is so configured as to hold the workpiece under suction. The chuck table 61 is movable in a feeding direction shown by an arrow X in FIG. 10 by feeding means (not shown) and also movable in an indexing direction shown by an arrow Y in FIG. 10 by indexing means (not shown).

The cutting means 62 includes a spindle housing 621 extending in a substantially horizontal direction, a rotating spindle 622 rotatably supported to the spindle housing 621, and a cutting blade 623 mounted on the front end portion of the rotating spindle 622. The rotating spindle 622 is rotated in the direction shown by an arrow C in FIG. 10 by a servo motor (not shown) provided in the spindle housing 621. For example, the cutting blade 623 is an electroformed blade obtained by bonding diamond abrasive grains having a grain size of 3 pm with a nickel plating. The cutting blade 623 has a thickness of 20 pm. The imaging means 63 is mounted on the front end portion of the spindle housing 621. The imaging means 63 includes an ordinary imaging device (CCD) for imaging the workpiece by using visible light, infrared light applying means for applying infrared light to the workpiece, an optical system for capturing the infrared light applied to the workpiece by the infrared light applying means, and an imaging device (infrared CCD) for outputting an electrical signal corresponding to the infrared light captured by the optical system. An image signal output from the imaging means 63 is transmitted to control means (not shown).

The stacking wafer dividing step using the cutting apparatus 6 is performed in the following manner. As shown in FIG. 10, the stacking wafer 3 bonded to the substrate 4 is placed on the chuck table 61 in the condition where the dicing tape T attached to the back side 4b of the substrate 4 comes into contact with the upper surface of the chuck table 61. By operating suction means (not shown), the unit of the stacking wafer 3 and the substrate 4 is held under suction on the chuck table 61 through the dicing tape T (wafer holding step). Accordingly, the back side 3b of the stacking wafer 3 bonded to the front side 4a of the substrate 4 held on the chuck table 61 is oriented upward. The chuck table 61 thus holding the unit of the stacking wafer 3 and the substrate 4 under suction is moved to a position directly below the imaging means 63 by the feeding means.

When the chuck table 61 is positioned directly below the imaging means 63, an alignment operation is performed by the imaging means 63 and the control means to detect a cutting area of the stacking wafer 3. More specifically, the imaging means 63 and the control means perform the alignment between the cutting blade 623 and the streets 31 extending in a first direction on the front side 3a of the stacking wafer 3 (alignment step). Similarly, the imaging means 63 and the control means perform the alignment in a cutting area for the other streets 31 extending in a second direction perpendicular to the first direction on the front side 3a of the stacking wafer 3. Although the front side 3a of the stacking wafer 3 on which the streets 31 are formed is oriented upward, the streets 31 can be imaged from the back side 3b of the stacking wafer 3 because the imaging means 63 includes the infrared light applying means for applying infrared light, the optical system for capturing the infrared light, and the imaging means (infrared CCD) for outputting an electrical signal corresponding to the infrared light as mentioned above.

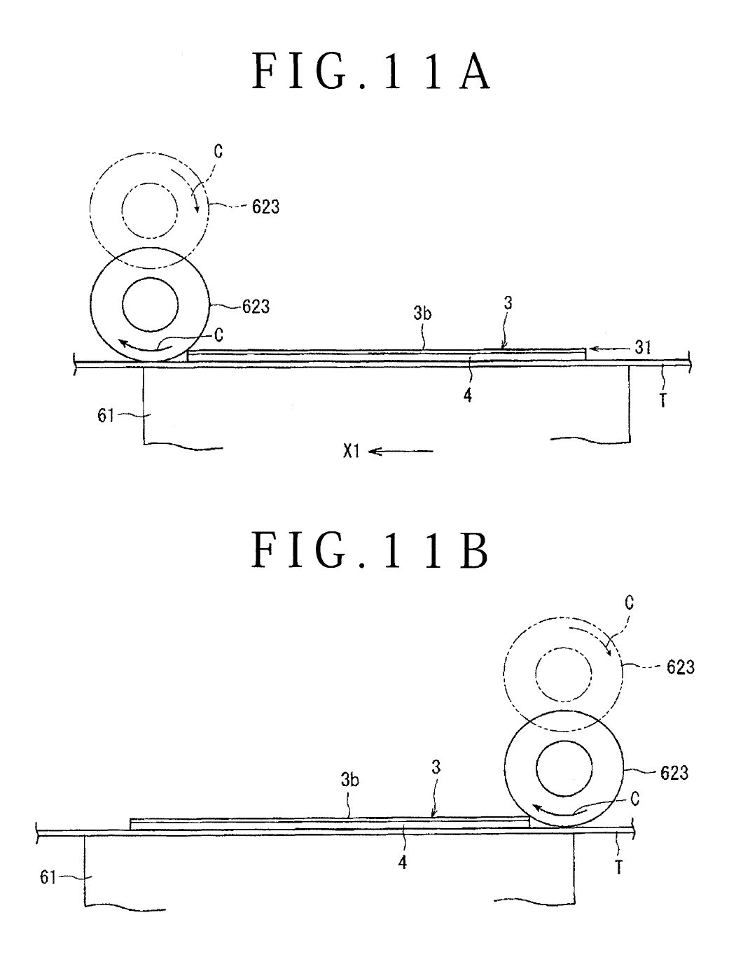

After performing the alignment operation for detecting the cutting area of the stacking wafer 3 held on the chuck table 61, the chuck table 61 holding the stacking wafer 3 is moved to a cutting start position in the cutting area below the cutting blade 623. At this cutting start position, one end (left end as viewed in FIG. 11A) of one of the streets 31 extending in the first direction is positioned on the right side of the cutting blade 623 by a predetermined amount (cutting start position setting step). When the stacking wafer 3 is set at this cutting start position as mentioned above, the cutting blade 623 is rotated in the direction shown by an arrow C in FIG. 11A and simultaneously moved down from a standby position shown by a phantom line in FIG. 11A to a working position shown by a solid line in FIG. 11A, thus performing an infeed operation by a predetermined amount. This working position of the cutting blade 623 is set so that the outer circumference of the cutting blade 623 reaches the dicing tape T.

After performing the infeed operation of the cutting blade 623, the chuck table 61 is moved at a feed speed of 50 to 150 mm/sec, for example, in the direction shown by an arrow X1 in FIG. 11A as rotating the cutting blade 623 at a rotational speed of 20000 rpm, for example, in the direction shown by the arrow C. As a result, the stacking wafer 3 and the substrate 4 are cut along the target street 31 extending in the first direction (stacking wafer dividing step). When the other end (right end as viewed in FIG. 11B) of the target street 31 extending in the first direction reaches a position on the left side of the cutting blade 623 by a predetermined amount, the movement of the chuck table 61 is stopped. Thereafter, the cutting blade 623 is raised to a retracted position shown by a phantom line in FIG. 11B.

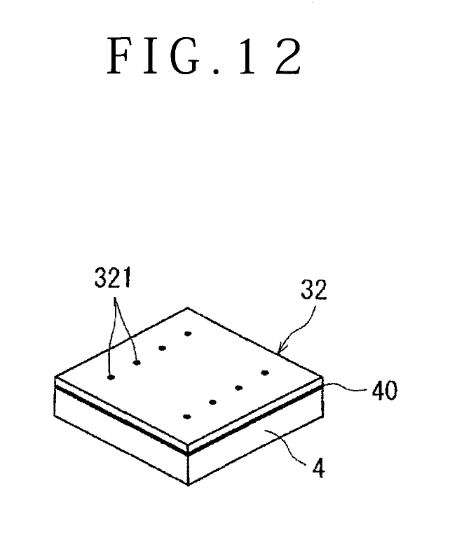

After performing the stacking wafer dividing step along all of the streets 31 extending in the first direction on the stacking wafer 3, the chuck table 61 is rotated 90° to similarly perform the stacking wafer dividing step along all of the streets 31 extending in the second direction perpendicular to the first direction. As a result, the unit of the stacking wafer 3 and the substrate 4 is divided along all of the crossing streets 31 extending in the first and second directions to obtain the individual second semiconductor devices 32. FIG. 12 shows one of these second semiconductor devices 32, wherein the substrate 4 is bonded to the front side (lower surface) of the second semiconductor device 32.

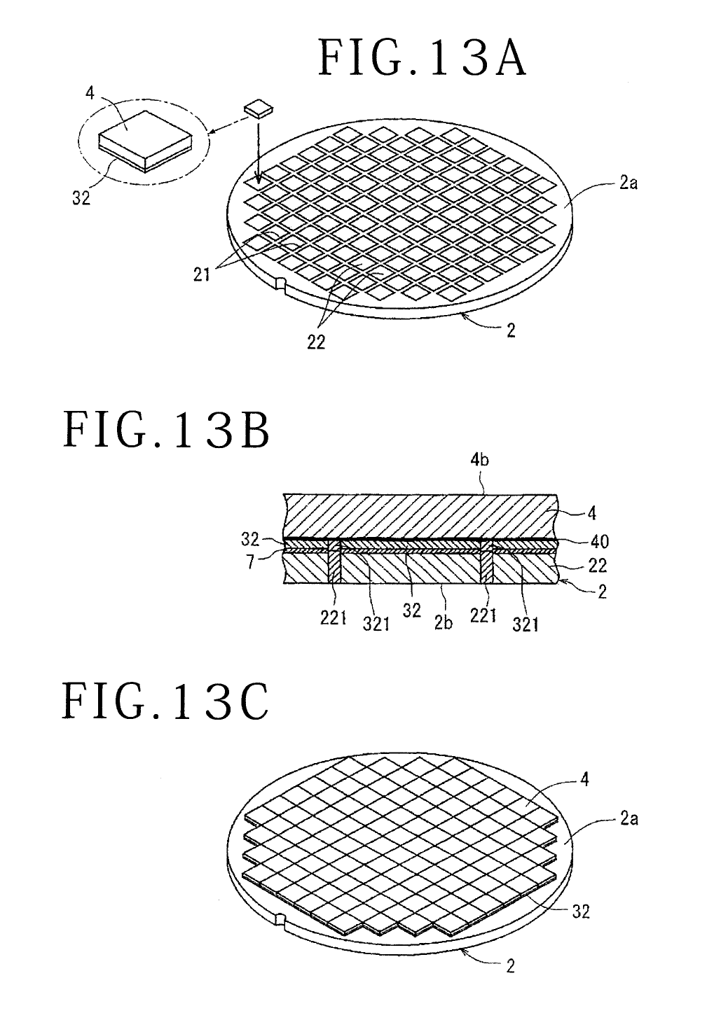

After performing the stacking wafer dividing step mentioned above, a second semiconductor device bonding step is performed in such a manner that the individual second semiconductor devices 32 are respectively stacked on the first semiconductor devices 22 formed on the front side 2a of the mother wafer 2 in the condition where the back side of each second semiconductor device 32 is opposed to the front side of each first semiconductor device 22, thereby bonding the electrodes exposed to the back side of each second semiconductor device 32 to the electrodes of each first semiconductor device 22 formed on the front side 2a of the mother wafer 2. More specifically, as shown in FIG. 13A, one of the individual second semiconductor devices 32 is stacked on a predetermined one of the plural first semiconductor devices 22 formed on the front side 2a of the mother wafer 2 in the condition where the back side of this second semiconductor device 32 is opposed to the front side of this first semiconductor device 22, and flip chip bonding is performed to respectively bond the electrodes 321 exposed to the back side of this second semiconductor device 32 to the electrodes 221 of this first semiconductor device 22 formed on the front side 2a of the mother wafer 2 as shown in FIG. 13B. This second semiconductor device bonding step is similarly performed for all of the first semiconductor devices 22 formed on the front side 2a of the mother wafer 2 as shown in FIG. 13C. Since this second semiconductor device bonding step is performed in the condition where the substrate 4 is bonded to the front side of each second semiconductor device 32, each second semiconductor device 32 having a very small thickness can be easily handled, so that the electrodes 321 exposed to the back side of each second semiconductor device 32 can be reliably bonded to the electrodes 221 of each first semiconductor device 22 formed on the front side 2a of the mother wafer 2. In this second semiconductor device bonding step, a resin 7 as an underfill material is preferably interposed between the front side 2a of the mother wafer 2 and the back side of each second semiconductor device 32 as shown in FIG. 13B.

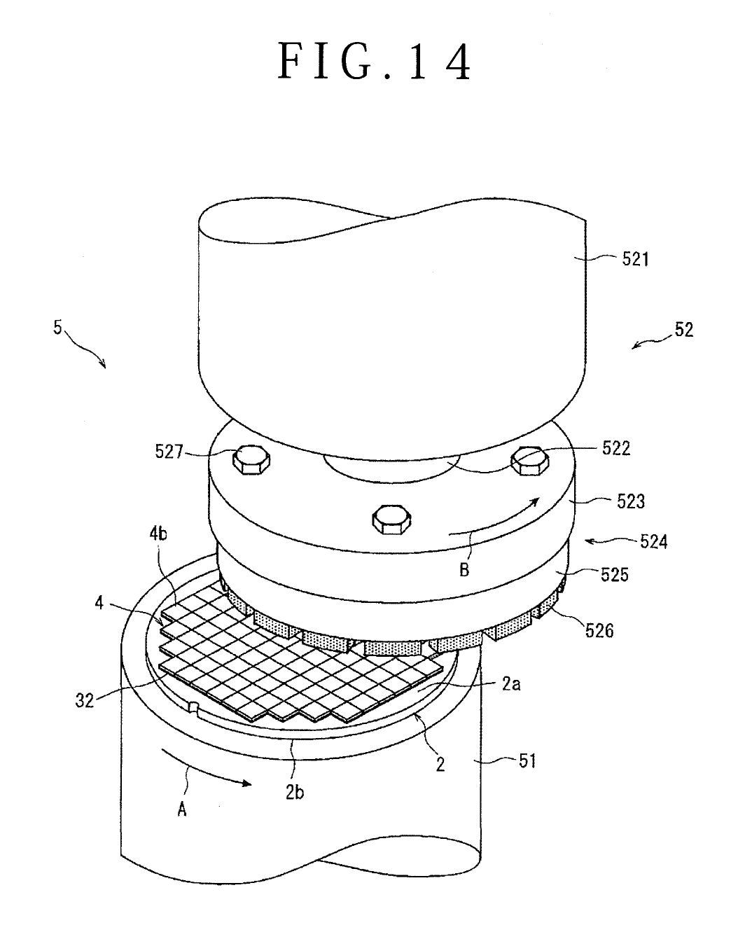

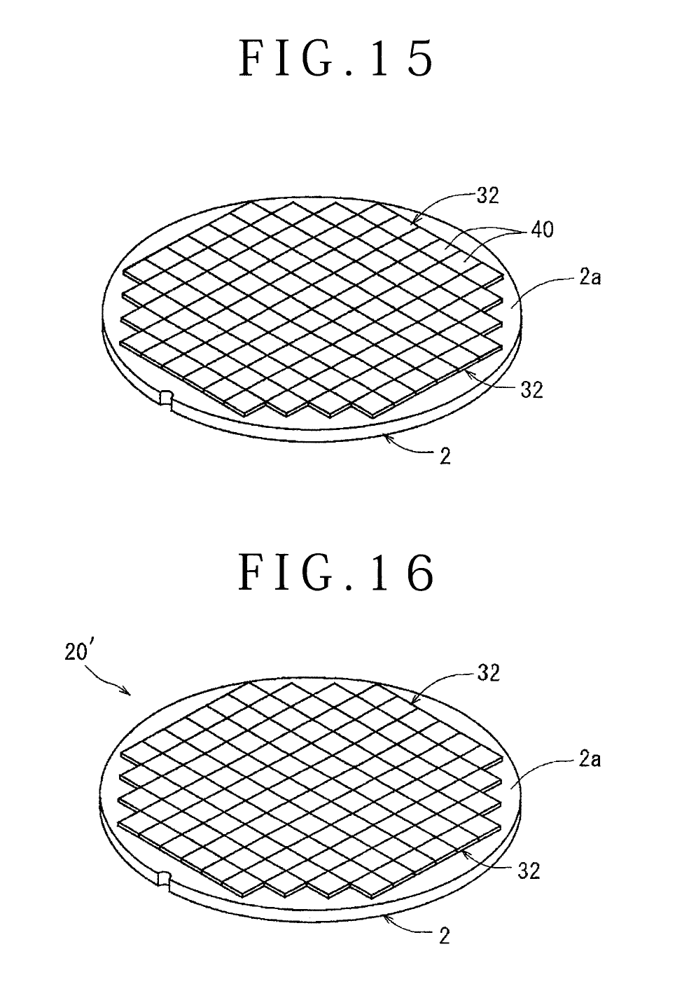

After performing the second semiconductor device bonding step mentioned above, a substrate removing step is performed in such a manner that the unit of the mother wafer 2, the second semiconductor devices 32, and the substrate 4 bonded together is held on a chuck table of a grinding apparatus and the substrate 4 bonded to the front side of each second semiconductor device 32 is ground to be removed. This substrate removing step may be performed by using the grinding apparatus 5 shown in FIG. 4. This substrate removing step using the grinding apparatus 5 is performed in the following manner. First, the unit of the mother wafer 2, the second semiconductor devices 32, and the substrate 4 bonded together is placed on the chuck table 51 in the condition where the back side 2b of the mother wafer 2 comes into contact with the upper surface (holding surface) of the chuck table 51 as shown in FIG. 14. In this condition, the suction means is operated to hold the unit of the mother wafer 2, the second semiconductor devices 32, and the substrate 4 on the chuck table 51 under suction. Accordingly, the back side 4b of the substrate 4 constituting this unit held on the chuck table 51 is oriented upward. In the condition where the unit of the mother wafer 2, the second semiconductor devices 32, and the substrate 4 is held under suction on the chuck table 51 as mentioned above, the chuck table 51 is rotated at 300 rpm, for example, in the direction shown by an arrow A in FIG. 14 and the grinding wheel 524 of the grinding means 52 is also rotated at 6000 rpm, for example, in the direction shown by an arrow B in FIG. 14. Thereafter, the grinding wheel 524 is lowered to bring the abrasive members 526 into contact with the back side 4b of the substrate 4. Thereafter, the grinding wheel 524 is fed downward at a feed speed of 1 μm/sec, for example, by an amount of 500 μm, for example. As a result, the substrate 4 having a thickness of 500 μm is ground to be removed from the front side of each second semiconductor device 32 as shown in FIG. 15.

In the substrate removing step, the substrate 4 bonded to the front side of each second semiconductor device 32 is removed by grinding, so that no load is applied to each second semiconductor device 32. In the condition after performing the substrate removing step, the bonding layer 40 used to bond the front side 4a of the substrate 4 to the front side 3a of the stacking wafer 3 in the substrate bonding step still remains on the front side of each second semiconductor device 32 as shown in FIG. 15.

Accordingly, the bonding layer 40 left on the front side of each second semiconductor device 32 is removed by using a solvent such as methyl ethyl ketone (bonding layer removing step). As a result, a stacked wafer 20′ shown in FIG. 16 is obtained. That is, the stacked wafer 20′ is composed of the mother wafer 2 and the second semiconductor devices 32 stacked on the mother wafer 2 so that the back side of each second semiconductor device 32 is opposed to the front side 2a of the mother wafer 2 and that the electrodes exposed to the back side of each second semiconductor device 32 are respectively bonded to the electrodes of each first semiconductor device 22 formed on the front side 2a of the mother wafer 2.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A manufacturing method for a stacked wafer configured by bonding a mother wafer having a plurality of first semiconductor devices and a stacking wafer having a plurality of second semiconductor devices, said manufacturing method comprising:
a substrate bonding step of bonding the front side of a substrate through a bonding layer to the front side of said stacking wafer;
a stacking wafer grinding step of holding a unit of said stacking wafer and said substrate bonded together on a chuck table of a grinding apparatus after performing said substrate bonding step and grinding the back side of said stacking wafer to reduce the thickness of said stacking wafer to a predetermined thickness;
a stacking wafer bonding step of stacking the unit of said stacking wafer and said substrate bonded together on said mother wafer in the condition where the back side of said stacking wafer is opposed to the front side of said mother wafer after performing said stacking wafer grinding step, thereby bonding electrodes exposed to the back side of each second semiconductor device to electrodes of each first semiconductor device formed on the front side of said mother wafer; and
a substrate removing step of holding a unit of said mother wafer, said stacking wafer, and said substrate bonded together on a chuck table of a grinding apparatus after performing said stacking wafer bonding step and grinding said substrate bonded to the front side of said stacking wafer to thereby remove said substrate from the front side of said stacking wafer.

2. A manufacturing method for a stacked wafer configured by bonding a mother wafer having a plurality of first semiconductor devices and a stacking wafer having a plurality of second semiconductor devices, said manufacturing method comprising:
a substrate bonding step of bonding the front side of a substrate through a bonding layer to the front side of said stacking wafer;
a stacking wafer grinding step of holding a unit of said stacking wafer and said substrate bonded together on a chuck table of a grinding apparatus after performing said substrate bonding step and grinding the back side of said stacking wafer to reduce the thickness of said stacking wafer to a predetermined thickness;
a stacking wafer dividing step of dividing said stacking wafer together with said substrate into said plurality of second semiconductor devices after performing said stacking wafer grinding step;
a second semiconductor device bonding step of respectively stacking said plurality of second semiconductor devices on said plurality of first semiconductor devices formed on the front side of said mother wafer in the condition where the back side of each second semiconductor device is opposed to the front side of each first semiconductor device after performing said stacking wafer dividing step, thereby bonding electrodes exposed to the back side of each second semiconductor device to electrodes of each first semiconductor device formed on the front side of said mother wafer; and
a substrate removing step of holding a unit of said mother wafer, said second semiconductor devices, and said substrate bonded together on a chuck table of a grinding apparatus after performing said second semiconductor device bonding step and grinding said substrate bonded to the front side of each second semiconductor device to thereby remove said substrate from the front side of each second semiconductor device.
